(19) United States
(12) Patent Application Publication
(10) Pub. No.: US 2020/0036086 A1
(43) Pub. Date: Jan. 30, 2020

(54) ELECTRONIC DEVICE AND COMMUNICATION APPARATUS

(71) Applicant: Murata Manufacturing Co., Ltd., Nagaokakyo-shi (JP)

(72) Inventors: Hirokazu YAZAKI, Nagaokakyo-shi (JP); Masahiro OZAWA, Nagaokakyo-shi (JP)

(21) Appl. No.: 16/589,447

(22) Filed: Oct. 1, 2019

Related U.S. Application Data
(63) Continuation of application No. PCT/JP2018/016398, filed on Apr. 23, 2018.

(30) Foreign Application Priority Data
May 19, 2017 (JP) 2017-099430

(51) Int. Cl. H01Q 1/24; H05K 7/02; H05K 9/00; H05K 1/16; H01Q 7/06; H01Q 1/38

(52) U.S. Cl. CPC H01Q 1/243; H05K 7/02; H01Q 1/38; H05K 1/16; H01Q 7/06; H05K 9/0075

(57) ABSTRACT

An electronic device includes a main substrate including an electronic component electrode thereon, a composite electronic component, and an antenna element. The composite electronic component includes a base substrate, a surface mount component mounted on the base substrate, a magnetic shielding layer covering the surface mount component, and is mounted on the electronic component electrode. The antenna element includes a flexible base and an antenna coil conductor disposed on the flexible base. The antenna element is disposed on the magnetic shielding layer of the composite electronic component.

### CROSS REFERENCE TO RELATED APPLICATIONS

This application claims the benefit of priority to Japanese Patent Application No. 2017-099430 filed on May 19, 2017 and is a Continuation Application of PCT Application No. PCT/JP2018/016398 filed on Apr. 23, 2018. The entire contents of each application are hereby incorporated herein by reference.

### BACKGROUND OF THE INVENTION

### 1. Field of the Invention

The present invention relates to an electronic device including an antenna, and more particularly, to an electronic device including an antenna used in near-field communication.

### 2. Description of the Related Art

Currently, many electronic devices include an antenna for short-range radio communication (NFC) are in practical use.

A mobile terminal described in International Publication No. 2013/183575 includes a housing, a motherboard, an antenna member, and an RFIC.

The antenna member is a flat film member and is produced by forming an antenna coil conductor on the surface of a flexible base. The flexible base has a terminal electrode formed thereon and connected to the antenna coil conductor. A magnetic sheet is attached to the flexible base, and the communication distance of the antenna is increased by the magnetic sheet. The antenna member is mounted on the inner surface of the housing.

The motherboard is disposed inside the housing, and the RFIC is mounted on the motherboard.

In this configuration, for connecting the RFIC to the antenna coil, a connecting member, such as a Pogo pin or spring-loaded connector, is vertically placed on the motherboard, and the connecting member is brought into contact with a terminal electrode of the antenna member.

In the conventional configuration described above, stress applied to the housing may produce friction between the terminal electrode and the connecting member, or may cause positional displacement between the terminal electrode and the connecting member. This may lead to defective contact between the antenna and the RFIC.

The inventors of preferred embodiments of the present invention discovered that when an antenna member is directly mounted on the motherboard, the distance to the outside of the housing (i.e., distance to the communication target) increases and it may be difficult to ensure reliable and stable communication. Additionally, since a space that accommodates the antenna member needs to be secured on the motherboard, it is difficult to achieve size reduction.

### SUMMARY OF THE INVENTION

Preferred embodiments of the present invention provide compact electronic devices that each reduce the occurrence of defective contact between the antenna and the RFIC and ensure reliable and stable communication.

An Electronic device according to a preferred embodiment of the present invention includes a main substrate including an electronic component electrode thereon, a composite electronic component, and an antenna element. The composite electronic component includes a base substrate, a surface mount component mounted on the base substrate, and a magnetic shielding layer covering the surface mount component, and is mounted on the electronic component electrode. The antenna element includes a flexible base and an antenna coil conductor disposed on the flexible base. The antenna element is disposed on the magnetic shielding layer of the composite electronic component so as to enable the magnetic shielding layer to define and function as a magnetic core of the antenna coil conductor.

In this configuration, the antenna element is disposed on the main substrate side. Therefore, unlike a conventional configuration in which the antenna element is disposed on the housing distant from the main substrate, this configuration ensures reliable connection between the antenna element and the main substrate. The magnetic shielding layer of the composite electronic component may also be used as a magnetic core of the antenna element.

An electronic device according to a preferred embodiment of the present invention is preferably configured as follows. The antenna element includes a wiring conductor connected to the antenna coil conductor. The main substrate includes an antenna electrode on which an RFIC chip is mounted, and the antenna electrode is connected to the RFIC chip. The wiring conductor of the antenna element is connected to the antenna electrode. This configuration enables the antenna element to be reliably connected to the RFIC chip on the main substrate, and improves connection reliability.

An electronic device according to a preferred embodiment of the present invention is preferably configured as follows. The composite electronic component includes a resin sealing layer covering the surface mount component. The magnetic shielding layer is made of a resin containing magnetic powder and is configured to cover top and side surfaces of the resin sealing layer. With this configuration, the top and side surfaces of the surface mount component are shielded by the magnetic shielding layer.

An electronic device according to a preferred embodiment of the present invention is preferably configured as follows. The composite electronic component includes a resin sealing layer covering the surface mount component. The magnetic shielding layer is a sintered magnetic ceramic body and is mounted on a top surface of the resin sealing layer. This configuration increases the permeability of the magnetic shielding layer and reduces loss.

In an electronic device according to a preferred embodiment of the present invention, the antenna coil conductor preferably has an area greater than a top surface of the composite electronic component, and is preferably disposed to extend from the top surface to a side surface of the composite electronic component. This configuration expands the opening of the antenna element.

An electronic device according to a preferred embodiment of the present invention is preferably configured as follows. The electronic device includes a plurality of composite electronic components. The plurality of composite electronic components are mounted side by side on the main substrate. The antenna coil conductor is disposed over magnetic shielding layers of the plurality of composite electronic components. With this configuration, the shape of the antenna element is not constrained by the size of one composite electronic component. This provides an additional degree of freedom in the design of the antenna element.

In an electronic device according to a preferred embodiment of the present invention, the base substrate is preferably a magnetic substrate. This configuration prevents magnetic fields generated by the antenna element from easily reaching the main substrate. Also, this configuration facilitates formation of an inductor with a high inductance value inside the magnetic substrate.

An electronic device according to a preferred embodiment of the present invention preferably includes a coil conductor capacitor connected to one end of the antenna coil conductor and configured to ground the one end. With this configuration, the inductance of the antenna coil conductor and the capacitance of the coil conductor define an LC filter. Therefore, by adjusting the inductance and the capacitance, it is possible to reduce loss in communication using the antenna element and to block noise emitted from the composite electronic component.

In an electronic device according to a preferred embodiment of the present invention, a metal shielding layer is preferably disposed between the surface mount component and the magnetic shielding layer. This configuration reduces propagation of noise emitted by the composite electronic component to the antenna element.

In an electronic device according to a preferred embodiment of the present invention, the metal shielding layer preferably includes a slit or a plurality of slits. This configuration reduces return current generated in the metal shielding layer by radio-frequency radiation from the antenna element.

An electronic device according to a preferred embodiment of the present invention preferably includes a metal shielding layer capacitor that grounds the metal shielding layer. With this configuration, the inductance of the metal shielding layer and the capacitance of the metal shielding layer define an LC filter. Therefore, by adjusting the inductance and the capacitance, it is possible to reduce loss in communication using the antenna element and to block noise emitted from the composite electronic component.

A metal shielding layer capacitor of an electronic device according to a preferred embodiment of the present invention is preferably defined by an inner-layer conductor pattern of the base substrate. This configuration enables the inner-layer conductor pattern to define an LC filter. This makes the area of the mounting surface smaller than that when mounting a capacitor. Also, wiring between the metal shielding layer and the capacitor is formed with a simple configuration.

An electronic device according to a preferred embodiment of the present invention is a communication apparatus in which the antenna element performs data communication. This configuration provides a communication apparatus that is structurally highly reliable and has high communication performance.

Preferred embodiments of the present invention are each able to provide a compact electronic device that reduces the occurrence of defective contact between the antenna and the RFIC and ensures reliable and stable communication.

The above and other elements, features, steps, characteristics and advantages of the present invention will become more apparent from the following detailed description of the preferred embodiments with reference to the attached drawings.

### BRIEF DESCRIPTION OF THE DRAWINGS

FIG. 1 is a lateral cross-sectional view illustrating a configuration of an electronic device 10 according to a first preferred embodiment of the present invention.

FIG. 2 is a plan view illustrating the configuration of the electronic device 10 according to the first preferred embodiment of the present invention.

FIG. 3 is a lateral cross-sectional view illustrating a portion of a configuration of an electronic device 10A according to a second preferred embodiment of the present invention.

FIG. 4 is a plan view illustrating an antenna element 50A according to the second preferred embodiment of the present invention.

FIG. 5 is a lateral cross-sectional view illustrating a portion of a configuration of an electronic device 10B according to a third preferred embodiment of the present invention.

FIG. 6A is a plan view illustrating a portion of a configuration of a first exemplary electronic device 10C according to a fourth preferred embodiment of the present invention, and FIG. 6B is a plan view illustrating a portion of a configuration of a second exemplary electronic device 10D according to the fourth preferred embodiment of the present invention.

FIG. 7 is a lateral cross-sectional view illustrating part of a configuration of an electronic device 10E according to a fifth preferred embodiment of the present invention.

FIG. 8 is a lateral cross-sectional view illustrating part of a configuration of an electronic device 10F according to a sixth preferred embodiment of the present invention.

FIG. 9 is a lateral cross-sectional view illustrating a portion of a configuration of an electronic device 10G according to a seventh preferred embodiment of the present invention.

FIG. 10 is a plan view illustrating a portion of a configuration of an electronic device 10H according to an eighth preferred embodiment of the present invention.

### DETAILED DESCRIPTION OF THE PREFERRED EMBODIMENTS

Preferred embodiments of the present invention will be described in detail below with reference to the accompanying drawings.

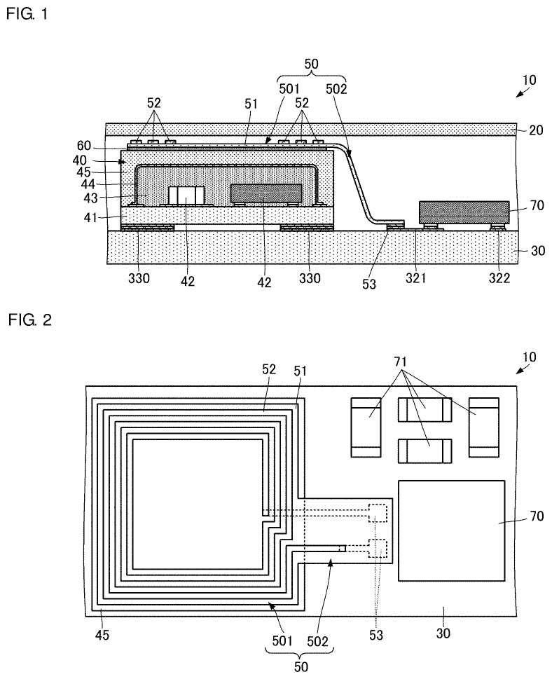

An electronic device according to a first preferred embodiment of the present invention will now be described with reference to the drawings. FIG. 1 is a lateral cross-sectional view illustrating a configuration of an electronic device 10 according to the first preferred embodiment of the present invention. FIG. 2 is a plan view illustrating the configuration of the electronic device 10 according to the first preferred embodiment of the present invention. FIG. 1 and FIG. 2 illustrate part of the electronic device 10, and FIG. 2 is a plan view which does not show a housing 20.

As illustrated in FIG. 1 and FIG. 2, the electronic device 10 preferably includes the housing 20, a main substrate 30, a composite electronic component 40, an antenna element 50, an adhesive layer 60, a Radio Frequency Integrated Circuit (RFIC) 70, and mounted electronic components 71.

The housing 20 includes a hollow and is preferably defined by combining a first member and a second member.

The main substrate 30 is preferably a printed wiring board and is defined, for example, by a resin multilayer substrate. While not shown, the main substrate 30 preferably includes various types of inner-layer electrodes and outer-surface electrodes, such as wiring conductors and ground conductors, and includes various types of electronic components mounted thereon. The main substrate 30 is mounted on the first member (not shown) of the housing 20.

The main substrate 30 also preferably includes land conductors 321, 322, and 330 on the surface thereof adjacent to the second member (denoted by reference numeral 20 in FIG. 1) of the housing 20. The land conductors 321, 322, and 330 are connected, in a predetermined circuit pattern, to the various types of inner-layer electrodes and the various types of electronic components (not shown) described above.

The composite electronic component 40 preferably includes a base substrate 41, a plurality of surface mount components 42, a resin sealing layer 43, a metal shielding layer 44, and a magnetic shielding layer 45. The base substrate 41 is a magnetic substrate including wiring patterns on the front and back surfaces thereof and also internally. The plurality of surface mount components 42 are mounted on the front surface of the base substrate 41. The plurality of surface mount components 42 and the wiring patterns provided on the front and back surfaces of, and inside, the base substrate 41 enable the composite electronic component 40 to perform its function. By using, for example, a switching element, a capacitor, and a coil as the surface mount components 42, the composite electronic component 40 preferably defines and functions, for example, as a DC-to-DC converter that supplies power to the RFIC 70.

The resin sealing layer 43 covers the plurality of surface mount components 42. The resin sealing layer 43 is preferably made of an electrically insulating material. The metal shielding layer 44 covers the resin sealing layer 43. With this configuration, the top and side surfaces of the plurality of surface mount components 42 are covered by the metal shielding layer 44. This configuration reduces or prevents leakage of high-frequency noise from the plurality of surface mount components 42 to the outside.

The magnetic shielding layer 45 is preferably made of a resin containing magnetic powder (magnetic powder-containing resin), for example. The magnetic shielding layer 45 covers the metal shielding layer 44. With this configuration, the top and side surfaces of the plurality of surface mount components 42 are covered by the magnetic shielding layer 45. At the same time, the back side of the plurality of surface mount components 42 is covered by the base substrate 41 defined by a magnetic substrate. This configuration reduces or prevents leakage of low-frequency noise from the plurality of surface mount components 42 to the outside.

The antenna element 50 preferably includes a flexible base 51, an antenna coil conductor 52, and wiring conductors 53. The antenna element 50 preferably includes a main portion 501 and a wiring portion 502. The flexible base 51 is preferably a flat film=shaped member.

The antenna coil conductor 52 is a planar spiral conductor with a central opening having a predetermined area. The shape of the antenna coil conductor 52 (e.g., the number of turns of the spiral, the area of the opening) is set on the basis of, for example, the frequency and the communication distance of the near-field communication achieved by the antenna element 50. The main portion 501 of the antenna element 50 is defined by a portion of the flexible base 51 which includes the antenna coil conductor 52 provided thereon.

The wiring conductors 53 are preferably linear conductors connected to the antenna coil conductor 52. The wiring portion 502 of the antenna element 50 is defined by a portion of the flexible base 51 including the wiring conductors 53 provided thereon.

The composite electronic component 40, the antenna element 50, the RFIC 70, and the mounted electronic components 71 are preferably disposed inside the housing 20 on the side of the main substrate 30 including the land conductors 321, 322, and 330 provided thereon.

Specifically, the composite electronic component 40 is mounted on the land conductors 330 using terminal conductors on the back surface of the base substrate 41. The RFIC 70 is mounted on the land conductors 321 and 322. The wiring conductors 53 of the antenna element 50 are connected to the land conductor 321. With this configuration, the antenna element 50 is electrically connected to the RFIC 70. This enables the electronic device 10 to define and function as a communication apparatus. Additionally, the antenna element 50 and the RFIC 70 are connected to each other by being individually mounted on the land conductor 321 of the main substrate 30. This does not require the use of, for example, a conventional pin and improves reliability of connection between the antenna element 50 and the RFIC 70. The mounted electronic components 71 are mounted on land conductors (not shown).

As illustrated in FIG. 1 and FIG. 2, the antenna element is preferably disposed on the top surface of the composite electronic component 40. More specifically, the main portion 501 of the antenna element 50 is disposed on the top surface of the composite electronic component 40. The antenna element 50 is disposed such that the flexible base 51 is closer to the composite electronic component 40 than the antenna coil conductor 52 is. The antenna element 50 is mounted on the composite electronic component 40, with the adhesive layer 60 interposed therebetween. The adhesive layer 60 is preferably made of a material with electrical insulating properties.

In this configuration, without attaching the antenna element 50 to the second member of the housing 20, the antenna coil conductor 52 of the antenna element 50 is able to be spaced apart from the main substrate 30 and disposed close to the second member of the housing 20. Additionally, the magnetic shielding layer 45 of the composite electronic component 40 is disposed close to the back side of the antenna coil conductor 52. The magnetic shielding layer 45 thus also defines and functions as a magnetic core of the antenna element 50. This allows the antenna coil conductor 52 to be spaced apart from the main substrate 30 including many electrode patterns, and increases the communication distance of the antenna element 50 without requiring a dedicated magnetic core. Since the electronic device 10 does not require a magnetic core specifically designed for the antenna element 50, a reduction in size and thickness is achieved.

The term magnetic core refers to a component that strengthens the magnetic field interlinked with the antenna coil conductor. That is, the magnetic core may be disposed inside a helical coil to define and function as a core, or may be disposed along the back side of a planar coil, such as the antenna coil conductor 52.

As illustrated in FIG. 1 and FIG. 2, the antenna element 50 is preferably disposed over the composite electronic component 40 having a function different from that of the electronic device 10. This requires less space than directly mounting the antenna element 50 on the main substrate 30, and enables size reduction of the electronic device 10.

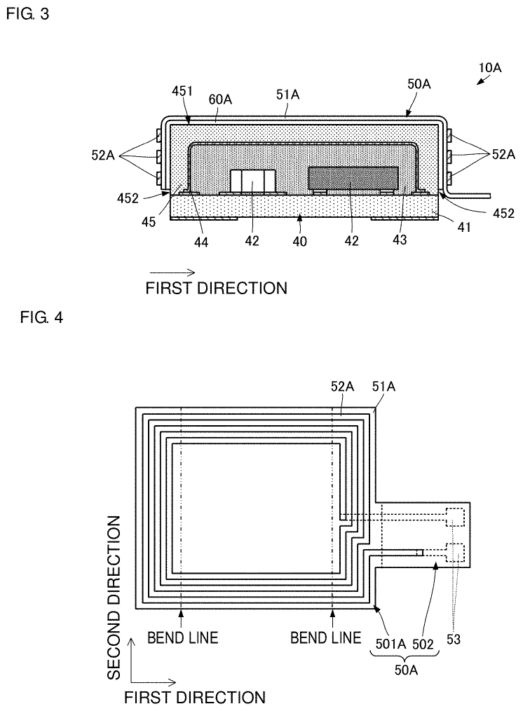

An electronic device according to a second preferred embodiment of the present invention will now be described with reference to the drawings. FIG. 3 is a lateral cross-sectional view illustrating a portion of a configuration of an electronic device 10A according to the second preferred embodiment of the present invention. FIG. 3 only illustrates a relationship between the composite electronic component 40 and an antenna element 50A. FIG. 4 is a plan view illustrating the antenna element 50A according to the second preferred embodiment of the present invention.

As illustrated in FIG. 3 and FIG. 4, the electronic device 10A according to the second preferred embodiment preferably differs from the electronic device 10 according to the first preferred embodiment in the shape and layout of the antenna element 50A. The remaining configurations of the electronic device 10A are preferably the same or substantially the same as those of the electronic device 10, and the description of the same portions will be omitted.

The antenna element 50A preferably includes a flexible base 51A and an antenna coil conductor 52A, and is defined by a main portion 501A and the wiring portion 502. The flexible base 51A defining the main portion 501A is preferably shaped to be longer in one direction than the flexible base 51 defining the main portion 501 described in the first preferred embodiment. Specifically, the length of the flexible base 51A defining the main portion 501A in a first direction is greater than the length of the composite electronic component 40 in the first direction. The length of the flexible base 51A defining the main portion 501A in a second direction is preferably the same or substantially the same as the length of the composite electronic component 40 in the second direction. The antenna coil conductor 52A is disposed near both ends of the main portion 501A in the first direction. This configuration increases the area of an opening surrounded by the antenna coil conductor 52A in the antenna element 50A, and thus improves radiation characteristics of the antenna element 50A.

As illustrated in FIG. 3, the antenna element 50A is mounted on a top surface 451 and two side surfaces 452 of the magnetic shielding layer 45 of the composite electronic component 40, with an adhesive layer 60A interposed therebetween. The two side surfaces 452 are opposite to each other and contiguous with the top surface 451. The antenna coil conductor 52A is disposed on the side surfaces 452 of the composite electronic component 40. With this configuration, where the antenna coil conductor 52A is disposed on the top surface 451 and the two side surfaces 452 opposite each other, improved directivity of the antenna element 50A is achieved.

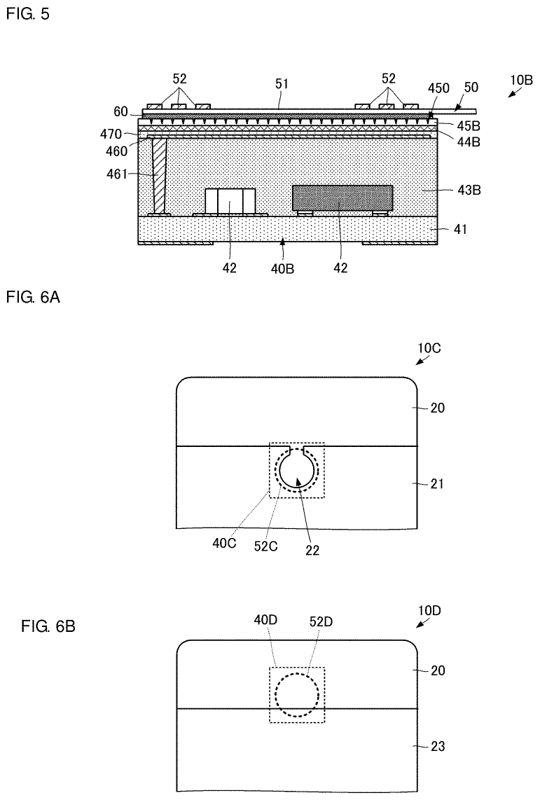

An electronic device according to a third preferred embodiment of the present invention will now be described with reference to the drawings. FIG. 5 is a lateral cross-sectional view illustrating a portion of a configuration of an electronic device 10B according to the third preferred embodiment of the present invention. FIG. 5 only illustrates a relationship between a composite electronic component 40B and the antenna element 50.

As illustrated in FIG. 5, the electronic device 10B according to the third preferred embodiment preferably differs from the electronic device 10 according to the first preferred embodiment in the structure of the composite electronic component 40B. The remaining configurations of the electronic device 10B are preferably the same or substantially the same as those of the electronic device 10, and the description of the same portions will be omitted.

The composite electronic component 40B includes the base substrate 41, the plurality of surface mount components 42, a resin sealing layer 43B, a metal shielding layer 44B, and a magnetic shielding layer 45B.

The resin sealing layer 43B covers the plurality of surface mount components 42 and the front surface of the base substrate 41. A rectangular or substantially rectangular ground conductor pattern 460 is provided on the top surface of the resin sealing layer 43B, that is, on the surface of the resin sealing layer 43B opposite the surface thereof in contact with the base substrate 41. The ground conductor pattern 460 is connected to a ground land conductor on the front surface of the base substrate 41 by a via conductor 461 passing through the resin sealing layer 43B in the thickness direction. The ground land conductor is connected by an inner-layer conductor pattern (not shown) to a ground conductor (not shown).

The magnetic shielding layer 45B is preferably flat and is defined by a sintered magnetic ceramic body. Using the sintered magnetic ceramic body ensures uniform permeability throughout the magnetic shielding layer 45B, and makes it easier to achieve low loss and high permeability than with resin containing magnetic powder. The magnetic shielding layer 45B is thus able to be produced, which is a thin layer with high permeability and low loss. The magnetic shielding layer 45B is preferably provided with a plurality of slits 450. The slits 450 are not defined throughout the thickness of the magnetic shielding layer 45B. That is, the magnetic shielding layer 45B preferably includes a plurality of thicker portions connected by thinner portions defined by the slits 450. With the slits 450, it is possible to improve flexibility of the magnetic body while reducing degradation of its shielding performance, and to facilitate mounting of the magnetic shielding layer 45B on another component.

The metal shielding layer 44B is preferably a flat film-shaped layer and is provided on the back surface of the magnetic shielding layer 45B (i.e., on the surface without the slits 450).

A composite shielding member of the magnetic shielding layer 45B and the metal shielding layer 44B is mounted on the top surface of the resin sealing layer 43B and the ground conductor pattern 460, with a conductive adhesive layer 470 interposed therebetween. The composite shielding member covers the top surface of the resin sealing layer 43B and the entire or substantially the entire surface of the ground conductor pattern 460.

The antenna element 50 is mounted on the front surface of the magnetic shielding layer 45B of the composite shielding member, with the adhesive layer 60 interposed therebetween.

With this configuration, the same advantageous operations and effects as those of the first preferred embodiment are still able to be achieved. Additionally, since the magnetic shielding layer 45B, which is a high-permeability low-loss layer, defines and functions as a magnetic core extending along the axial direction of the antenna element 50 of helical type, a thin antenna with good radiation characteristics is able to be produced.

An electronic device according to a fourth preferred embodiment of the present invention will now be described with reference to the drawings. FIG. 6A is a plan view illustrating a portion of a configuration of a first exemplary electronic device 10C according to the fourth preferred embodiment of the present invention, and FIG. 6B is a plan view illustrating a portion of a configuration of a second exemplary electronic device 10D according to the fourth preferred embodiment of the present invention.

As illustrated in FIGS. 6A and 6B, the electronic devices 10C and 10D according to the fourth preferred embodiment preferably differ from the electronic device 10 according to the first preferred embodiment in that the electronic devices 10C and 10D include metal portions 21 and 23, respectively, in their respective housings 20, and that the electronic devices 10C and 10D include antenna coil conductors 52C and 52D, respectively. The remaining configurations of the electronic devices 10C and 10D are the same or substantially the same as those of the electronic device 10, and the description of the same portions will be omitted.

As illustrated in FIG. 6A, the electronic device 10C includes the metal portion 21 as a portion of the housing 20. The metal portion 21 includes a notch 22 in plan view.

The antenna coil conductor 52C is preferably a spiral conductor having a winding axis orthogonal or substantially orthogonal to the housing 20. The antenna coil conductor 52C is disposed such that the central opening of the spiral shape overlaps the notch 22 in a plan view of the housing 20.

A composite electronic component 40C preferably has the same or substantially the same structure as the composite electronic components 40 and 40B described in the aforementioned preferred embodiments. The composite electronic component 40C is disposed opposite the housing 20 with respect to the antenna coil conductor 52C, so as to overlap the antenna coil conductor 52C in plan view of the housing 20.

As illustrated in FIG. 6B, the electronic device 10D includes the metal portion 23 as a portion of the housing 20.

The antenna coil conductor 52D is preferably a spiral conductor having a winding axis orthogonal or substantially orthogonal to the housing 20. The antenna coil conductor 52D is disposed such that at least a portion of the central opening of the spiral shape does not overlap the metal portion 23 in plan view of the housing 20.

A composite electronic component 40D preferably has the same or substantially the same structure as the composite electronic components 40 and 40B described in the aforementioned preferred embodiments. The composite electronic component 40D is disposed opposite the housing 20 with respect to the antenna coil conductor 52D, so as to overlap the antenna coil conductor 52D in plan view of the housing 20.

With the configurations described above, the same advantageous operations and effects as those of the first and third preferred embodiments are still able to be achieved.

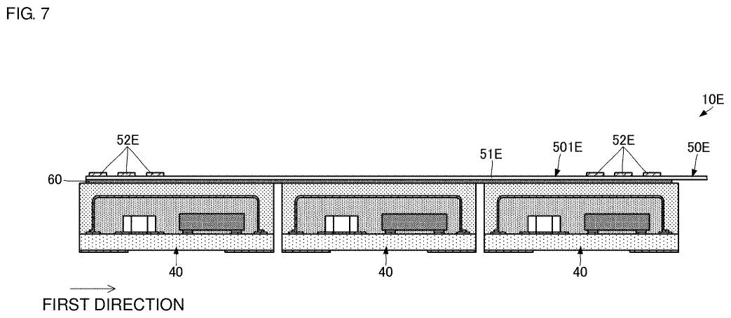

An electronic device according to a fifth preferred embodiment of the present invention will now be described with reference to the drawings. FIG. 7 is a lateral cross-sectional view illustrating a portion of a configuration of an electronic device 10E according to the fifth preferred embodiment of the present invention. FIG. 7 illustrates only a relationship between the composite electronic component 40 and an antenna element 50E.

As illustrated in FIG. 7, the electronic device 10E according to the fifth preferred embodiment preferably differs from the electronic device 10 according to the first preferred embodiment in that it includes three composite electronic components 40, and also preferably differs therefrom in the shape of the antenna element 50E. The remaining configurations of the electronic device 10E are preferably the same or substantially the same as those of the electronic device 10, and the description of the same portions will be omitted.

The electronic device 10E preferably includes three composite electronic components 40. The three composite electronic components 40 may have either the same function or different functions. The three composite electronic components 40 are mounted on the main substrate (not shown) side by side along the first direction.

The antenna element 50E preferably includes a flexible base 51E and an antenna coil conductor 52E. The flexible base 51E defining a main portion 501E is long enough in the first direction to cover the entire or substantially the entire top surfaces of the three composite electronic components 40. The antenna coil conductor 52E is disposed near both ends of the flexible base 51E defining the main portion 501E in the first direction.

This configuration is able to further expand the opening of the antenna element 50E. In other words, the opening area of the antenna element 50E is not limited to the area of the top surface of one composite electronic component 40. Therefore, the antenna element 50E may be shaped as required to achieve antenna characteristics (e.g., frequency, radiation characteristics) of the antenna element 50E.

Although three composite electronic components 40 are shown arranged side by side in the present preferred embodiment, the number of the composite electronic components 40 may be two, or more than three. Although the present preferred embodiment illustrates the composite electronic components 40 one-dimensionally arranged in the first direction, a plurality of composite electronic components 40 may be arranged in a two-dimensional region where the antenna element 50E is disposed. This provides an additional degree of freedom in the design of the antenna element 50E.

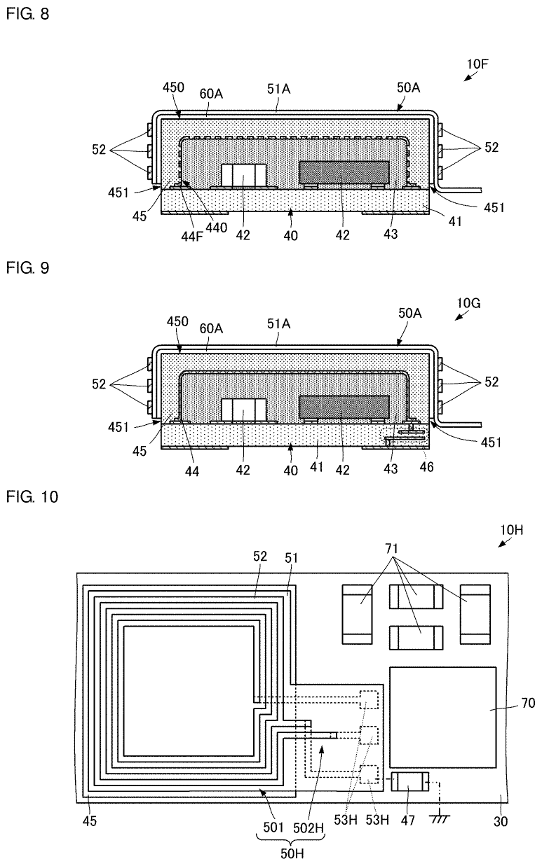

An electronic device according to a sixth preferred embodiment of the present invention will now be described with reference to the drawings. FIG. 8 is a lateral cross-sectional view illustrating a portion of a configuration of an electronic device 10F according to the sixth preferred embodiment of the present invention. FIG. 8 illustrates only a relationship between the composite electronic component 40 and the antenna element 50A.

As illustrated in FIG. 8, the electronic device 10F according to the sixth preferred embodiment preferably differs from the electronic device 10A according to the second preferred embodiment in the configuration of a metal shielding layer 44F. The remaining configurations of the electronic device 10F are preferably the same or substantially the same as those of the electronic device 10A, and the description of the same portions will be omitted.

The metal shielding layer 44F is provided with a plurality of slits 440, which divide the metal shielding layer 44F into multiple pieces. With this configuration, radio-frequency radiation from the antenna element 50A does not cause return current in the metal shielding layer 44F. This reduces characteristic degradation of the antenna element 50A caused by the presence of the metal shielding layer 44F.

The size and the number of the slits 440 are preferably determined such that while performance of blocking noise emitted from the surface mount components 42 is maintained at a predetermined level, the size of each piece is able to be appropriately set in accordance with the frequency of radio-frequency radiation transmitted and received by the antenna element 50A.

The present preferred embodiment describes an example which involves using the slits 440, but alternative openings or the like may be provided. The slits 440 and the openings may be arranged in a portion of the metal shielding layer 44F where the strength of electromagnetic field generated by the antenna element 50A is high.

An electronic device according to a seventh preferred embodiment of the present invention will now be described with reference to the drawings. FIG. 9 is a lateral cross-sectional view illustrating a portion of a configuration of an electronic device 10G according to the seventh preferred embodiment of the present invention. FIG. 9 illustrates only a relationship between the composite electronic component 40 and the antenna element 50A.

As illustrated in FIG. 9, the electronic device 10G according to the seventh preferred embodiment preferably differs from the electronic device 10A according to the second preferred embodiment in that it further includes a capacitor 46. The remaining configurations of the electronic device 10G are preferably the same or substantially the same as those of the electronic device 10A, and the description of the same portions will be omitted.

As illustrated in FIG. 9, the electronic device 10G preferably includes the capacitor 46 in the composite electronic component 40. In the present preferred embodiment, the base substrate 41 of the composite electronic component 40 is a dielectric substrate. The base substrate 41 includes flat inner-layer conductor patterns opposite to each other. The capacitor 46 is defined by the opposite inner-layer conductor patterns. One of the opposite inner-layer conductor patterns is connected to the metal shielding layer 44, and the other is connected to the ground conductor. The metal shielding layer 44 is thus grounded via the capacitor 46.

In this configuration, the inductance of the metal shielding layer 44 and the capacitance of the capacitor 46 define an LC series resonance circuit. By adjusting the inductance of the metal shielding layer 44 and the capacitance of the capacitor 46, radio-frequency signals in the HF band transmitted and received by the antenna element 50A are able to be reflected, and noise emitted from the surface mount components 42 and having frequencies higher than the HF band is able to be guided to the ground potential.

Therefore, this configuration makes it possible to reduce characteristic degradation of the antenna element 50A caused by the presence of the metal shielding layer 44 while reducing or preventing emission of high-frequency noise from the surface mount components 42 to the outside.

An electronic device according to an eighth preferred embodiment of the present invention will now be described with reference to the drawings. FIG. 10 is a plan view illustrating a portion of a configuration of an electronic device 10H according to the eighth preferred embodiment of the present invention. Note that the housing is not shown in FIG. 10.

As illustrated in FIG. 10, the electronic device 10H according to the eighth preferred embodiment preferably differs from the electronic device 10 according to the first preferred embodiment in the structure of an antenna element 50H, and also preferably differs therefrom in that it further includes a capacitor 47. The remaining configurations of the electronic device 10H are preferably the same or substantially the same as those of the electronic device 10, and the description of the same portions will be omitted.

In the electronic device 10H, the antenna element 50H includes the main portion 501 and a wiring portion 502H. The wiring portion 502H includes wiring conductors 53H that provide capacitor connection. The wiring conductors 53H that provide capacitor connection are connected to predetermined points of the antenna coil conductor 52.

The capacitor 47 is connected at one terminal thereof to the wiring conductor 53H and grounded at the other terminal thereof. This means that the antenna coil conductor 52 is grounded via the capacitor 47. For example, as illustrated in FIG. 10, the capacitor 47 is defined by a mount element mounted on the main substrate 30.

In this configuration, the inductance of the antenna coil conductor 52 and the capacitance of the capacitor 47 define an LC series resonance circuit. By adjusting the capacitance of the capacitor 47 and adjusting the inductance of the antenna coil conductor 52 where necessary, noise emitted from the surface mount components 42 and having frequencies higher than the HF band is able to be guided to the ground potential while radio-frequency signals in the HF band are transmitted and received by the antenna element 50H with low loss.

Therefore, this configuration enables low-loss communication using the antenna element 50H while reducing or preventing emission of high-frequency noise from the surface mount components 42 to the outside.

Although a magnetic substrate is used as the base substrate 41 of the composite electronic component 40 in predetermined ones of the preferred embodiments described above, the base substrate 41 may be a dielectric substrate. When the base substrate 41 is a magnetic substrate, however, a closed magnetic circuit of the surface mount components 42 is defined and this enables more reliable reduction or prevention of leakage of low-frequency noise from the surface mount components 42 to the outside of the composite electronic component 40.

In any of the preferred embodiments, except the preferred embodiment where the metal shielding layer includes slits and the preferred embodiment where a capacitor is connected to the metal shielding layer, the electronic device may include no metal shielding layer. In any of the preferred embodiments described above, the electronic device may include no resin sealing layer.

The configurations of the preferred embodiments described above may be combined as appropriate. By combining some configurations of the preferred embodiments, advantageous operations and effects, which vary depending on the combination, are able to be achieved.

While preferred embodiments of the present invention have been described above, it is to be understood that variations and modifications will be apparent to those skilled in the art without departing from the scope and spirit of the present invention. The scope of the present invention, therefore, is to be determined solely by the following claims.

What is claimed is:

1. An electronic device comprising:
a main substrate including an electronic component electrode thereon;
a composite electronic component including a base substrate, a surface mount component mounted on the base substrate, and a magnetic shielding layer covering the surface mount component, the composite electronic component being mounted on the electronic component electrode; and
an antenna element including a flexible base and an antenna coil conductor disposed on the flexible base; wherein
the antenna element is disposed on the magnetic shielding layer of the composite electronic component so as to enable the magnetic shielding layer to defined and function as a magnetic core of the antenna coil conductor.

2. The electronic device according to claim 1, wherein
the antenna element includes a wiring conductor connected to the antenna coil conductor;
the main substrate includes an antenna electrode including a Radio Frequency Integrated Circuit (RFIC) chip mounted thereon, the antenna electrode being connected to the RFIC chip; and
the wiring conductor of the antenna element is connected to the antenna electrode.

3. The electronic device according to claim 1, wherein
the composite electronic component includes a resin sealing layer covering the surface mount component; and
the magnetic shielding layer is made of a resin containing magnetic powder and covers top and side surfaces of the resin sealing layer.

4. The electronic device according to claim 1, wherein
the composite electronic component includes a resin sealing layer covering the surface mount component; and
the magnetic shielding layer is a sintered magnetic ceramic body and is mounted on a top surface of the resin sealing layer.

5. The electronic device according to claim 1, wherein the antenna coil conductor has an area greater than a top surface of the composite electronic component, and extends from a top surface to a side surface of the composite electronic component.

6. The electronic device according to claim 1, wherein
the electronic device includes a plurality of the composite electronic components;
the plurality of composite electronic components are mounted side by side on the main substrate; and
the antenna coil conductor is disposed over magnetic shielding layers of the plurality of composite electronic components.

7. The electronic device according to claim 1, wherein the base substrate is a magnetic substrate.

8. The electronic device according to claim 1, further comprising a coil conductor capacitor connected to one end of the antenna coil conductor, the coil conductor capacitor grounding the one end.

9. The electronic device according to claim 1, wherein a metal shielding layer is disposed between the surface mount component and the magnetic shielding layer.

10. The electronic device according to claim 9, wherein the metal shielding layer includes a slit or a plurality of slits.

11. The electronic device according to claim 9, further comprising a metal shielding layer capacitor that grounds the metal shielding layer.

12. The electronic device according to claim 11, wherein the metal shielding layer capacitor is defined by an inner-layer conductor pattern of the base substrate.

13. A communication apparatus, comprising:
the electronic device according to claim 1; wherein
the antenna element performs data communication.

14. The electronic device according to claim 1, wherein the antenna element is fixed to the magnetic shielding layer through an adhesive layer.

15. The electronic device according to claim 1, wherein the flexible base is closer to the composite electronic component than the antenna coil conductor is.

16. The electronic device according to claim 1, wherein the antenna coil conductor has an area greater than a top surface of the composite electronic component, and is disposed to extend from a top surface to two side surfaces of the composite electronic component, the two side surfaces being opposite to each other and contiguous with the top surface.

17. The electronic device according to claim 1, wherein
the composite electronic component includes a resin sealing layer covering the surface mount component; and
a rectangular ground conductor pattern is provided on the top surface of the resin sealing layer.

18. The electronic device according to claim 17, wherein the rectangular ground conductor pattern is connected to a ground land conductor on a front surface of the base substrate by a via conductor passing through the resin sealing layer.

19. The electronic device according to claim 1, wherein
the magnetic shielding layer includes a notch; and
the antenna coil conductor is a spiral conductor disposed such that a central opening of a spiral shape of the antenna coil conductor overlaps the notch in a plan view.

20. The electronic device according to claim 1, wherein
a plurality of the composite electronic components are provided; and
the an antenna element overlaps top surfaces of each of the plurality of the composite electronic components.
